(19) United States
(12) Patent Application Publication
(10) Pub. No.: US 2014/0054729 A1
(43) Pub. Date: Feb. 27, 2014

(54) MEMS DEVICE, ELECTRONIC APPARATUS, AND MANUFACTURING METHOD OF MEMS DEVICE

(71) Applicant: Seiko Epson Corporation, Tokyo (JP)

(72) Inventors: Yoji Kitano, Chino (JP); Takuya Kinugawa, Chino (JP)

(73) Assignee: Seiko Epson Corporation, Tokyo (JP)

(21) Appl. No.: 13/966,384

(22) Filed: Aug. 14, 2013

(30) Foreign Application Priority Data
Aug. 27, 2012 (JP) 2012-186181

(51) Int. Cl. B81B 3/00; B81C 1/00

(52) U.S. Cl. CPC B81B 3/0018; B81C 1/00134
USPC 257/415; 438/50

(57) ABSTRACT

A MEMS device includes a first oxide film that is laminated on a main surface of a wafer substrate, a lower-layer wire portion that is provided on the first oxide film, a nitride film that is laminated so as to cover the first oxide film and the lower-layer wire portion, a sidewall portion that is laminated on the nitride film and is formed in a frame shape, a cavity portion that is partitioned by the sidewall portion, and a MEMS structure that is disposed in the cavity portion, in which the nitride film includes a through hole reaching the lower-layer wire portion, and in which the MEMS structure is electrically connected to the lower-layer wire portion by an electrical connection portion provided in the through hole.

### BACKGROUND

1. Technical Field

The present invention relates to a MEMS device, an electronic apparatus, and a manufacturing method of the MEMS device.

2. Related Art

Generally, there is an electro-mechanical system structure having a structure which is called a micro-electro-mechanical system (MEMS) device formed using a micro-processing technique and is mechanically movable. For example, there is a MEMS device such as a vibrator, a sensor, or an actuator, which reads a capacitance variation or a unique vibration due to a minute displacement of a movable portion as a signal. In a case of this MEMS device, air resistance to displacement or vibration of the movable portion is reduced, and thereby it is possible to obtain more stable and better characteristics. For this reason, it is necessary to air-tightly seal a MEMS structure including the movable portion in a decompressed atmosphere so as to be maintained in a decompressed state.

For example, a MEMS device disclosed in JP-A-2009-105411 is to realize an electronic device in which electronic circuits such as a complementary metal oxide semiconductor (CMOS) circuit are integrated, and a MEMS structure is accommodated in a cavity portion (hereinafter, also referred to as a cavity) which is air-tightly sealed in a decompressed state. The cavity is formed by removing (release-etching) sacrificial layers such as an oxide film formed around the MEMS structure, and is maintained in a decompressed state by sealing an opening through which an etchant is introduced with a metal layer or the like in a decompressed atmosphere after being cleaned. With this structure, the decompressed and sealed MEMS structure and an electronic circuit can be integrated into one chip while suppressing an increase in costs, and thus it is possible to achieve a low cost and a small size of the electronic device.

However, in a structure of the MEMS device disclosed in JP-A-2009-105411, there is a problem such as a concern that a wire material extracted from inside of the cavity to outside thereof is required to be covered by an insulating layer at the extraction part, and this insulating layer is exposed to the inside of the cavity, and thus reliability may be reduced. Specifically, there is a concern that, in many cases of performing manufacturing by using a semiconductor manufacturing process, a silicon oxide film with a low etching resistance is used in the insulating layer, and thus an etchant may penetrate into the periphery of the cavity through the insulating layer in release-etching for forming the cavity and reliability of the device may be reduced. In other words, since the insulating layer with a low etching resistance is disposed at the wire extraction part, there is a concern that, for example, erosion of this part progresses due to excessive etching, an etchant leaks to the periphery thereof along the wire from the eroded part, and thus a wire of a peripheral electrical circuit may be corroded and electrical problems may occur.

In order to avoid the reduction in reliability, etching time is managed for preventing excessive etching. On the other hand, if etching is insufficient, there is a case where a sacrificial layer remains, and thus dimension accuracy of a MEMS structure is reduced, or the remaining sacrificial layer generates an outgas inside the cavity. In other words, it is necessary to perform strict management for appropriately setting etching time or etching conditions or suppressing etching disparity. In recent years, there is a problem such as a case where this management width (margin) decreases with the progress of further miniaturization of a MEMS device, and thereby a yield is reduced.

Further, in a case where a material which generates an outgas is used in the insulating layer of the wire extraction part, there is a problem in that the inside of the cavity is not maintained in a decompressed state, and characteristics of the MEMS device deteriorate. Particularly, a spin on glass (SOG) film for obtaining a favorable step coverage of an electrical wire layer tends to generate an outgas, and thus it is necessary to prevent the film from being exposed to or remaining in the inside of the cavity.

In contrast, it is considered that an insulating film of a wire extraction part is made to be unnecessary using a method disclosed in JP-A-2000-186933. Specifically, the method is that a wire formed of an n layer or a p layer which is diffused and is formed through ion implantation of impurities is disposed on a substrate under a nitride film which forms a bottom of a cavity and has a high etching resistance, and inside and outside of the cavity are electrically connected to each other using polysilicon of a wire connection portion which penetrates through the nitride film. However, in this method, there is a problem such as a case where a parasitic resistance (contact resistance) between the polysilicon of the wire connection part and the wire under the nitride film tends to increase, and, as a result, predetermined characteristics of the MEMS device cannot be obtained.

### SUMMARY

An advantage of some aspects of the invention is to solve at least a part of the problems described above, and the invention can be implemented as the following forms or application examples.

### Application Example 1

This application example is directed to a MEMS device including a first insulating layer that is laminated on a main surface of a substrate; a lower-layer wire portion that is disposed on the first insulating layer; a second insulating layer that is laminated on the first insulating layer and the lower-layer wire portion; a sidewall portion that is laminated on the second insulating layer and is formed in a frame shape; a cavity portion that is partitioned by the sidewall portion; and a MEMS structure that is disposed in the cavity portion, and in which the MEMS structure is electrically connected to the lower-layer wire portion by an electrical connection portion provided in a through hole.

With this configuration, a wire which is extracted to the outside of the cavity portion from the MEMS structure disposed inside the cavity portion is formed by the lower-layer wire portion provided under the second insulating layer and the electrical connection portion provided in the through hole part formed in the second insulating layer. Therefore, since the wire does not penetrate through the sidewall portion, the wire is not required to be insulated from the sidewall portion. In other words, even in a case where the sidewall portion is conductive (for example, in a case where the sidewall portion is formed by laminating a conductive layer forming a wire of the MEMS device), it is not necessary to provide a coat for insulating the sidewall portion from the electrical connection portion. As a result, an insulating layer such as, for example, a silicon oxide film, with a low etching resistance, which is frequently used in a semiconductor manufacturing process, is not exposed to the cavity portion. For this reason, in a case of forming the cavity portion by etching the sacrificial layers, even if excessive etching is performed, it does not happen that an etchant leaks to outside of the cavity portion due to erosion of the insulating layer with a low etching resistance. In addition, since the periphery of the sacrificial portion forming the cavity portion is formed only using a material with a high etching resistance such as a metal material, that is, an etching stopper, it is not necessary to strictly manage etching end timing unlike in the related art, and it is possible to take a large management width (margin) of an etching step. As a result, it is possible to perform not insufficient etching but sufficient release-etching without apprehending influence of excessive etching on reliability.

In addition, since an insulating layer such as a silicon oxide film which tends to generate an outgas does not remain in or is not exposed to inside of the cavity portion, the inside of the cavity portion can be maintained in a decompressed state.

As described above, according to the present embodiment, it is possible to provide a MEMS device having higher reliability through manufacturing steps of which management is further simplified.

### Application Example 2

This application example is directed to the MEMS device according to the application example, which further includes an electrical circuit portion including the first insulating layer, the second insulating layer, a conductive layer forming the MEMS structure, and an upper-layer wire portion and an interlayer insulating portion laminated and formed on the second insulating layer, in which the electrical connection portion is formed of an upper-layer wire layer which forms the upper-layer wire portion, and in which the cavity portion is formed by etching a sacrificial portion which is formed of an interlayer insulating layer forming the interlayer insulating portion.

With this configuration, the MEMS device further includes the electrical circuit portion, the electrical circuit portion includes the first insulating layer, the second insulating layer, the conductive layer forming the MEMS structure, and the upper-layer wire portion and the interlayer insulating portion laminated and formed on the second insulating layer. In addition, the electrical connection portion is formed of an upper-layer wire layer which forms the upper-layer wire portion, and the sacrificial portion for forming the cavity portion is formed of the interlayer insulating layer forming the interlayer insulating portion.

In other words, in this case, since the MEMS device can be formed using many constituent elements common to the electrical circuit portion included in the MEMS device, it is possible to manufacture and provide a MEMS device integrally formed with an electrical circuit while suppressing an increase in manufacturing costs due to an increase in the number of manufacturing steps.

### Application Example 3

This application example is directed to the MEMS device according to the application example, wherein the electrical connection portion is made of a metal material.

As in this configuration, the electrical connection portion is preferably made of a metal material. By the use of the metal material, it is possible to suppress an increase in parasitic resistance at the connection portion due to connection between the electrical connection portion and the lower-layer wire portion. As a result, it is possible to suppress deterioration in characteristics of a MEMS device and an increase in the number of manufacturing steps.

### Application Example 4

This application example is directed to the MEMS device according to the application example, wherein the area of the electrical connection portion is larger than the area of the through hole in plan view of the substrate.

As in this configuration, the area of the electrical connection portion is preferably larger than the area of the through hole in plan view of the substrate. By further increasing the area of the electrical connection portion, it is possible to increase the contact area with the MEMS structure and to thereby further reduce an electrical resistance at the connection portion. Further, since the electrical connection portion can cover the lower-layer wire portion which is exposed by the through hole, it does not happen that an etchant for etching a sacrificial layer enters the through hole and remains therein or leaks to a part such as the insulating layer for insulating the lower-layer wire portion and causes erosion. As a result, it is possible to provide a MEMS device with higher reliability.

### Application Example 5

This application example is directed to an electronic apparatus including the MEMS device according the application example.

With this configuration, the MEMS device according to the application example is included, and thereby it is possible to provide an electronic apparatus with higher reliability of which an increase in costs is suppressed.

### Application Example 6

This application example is directed to a manufacturing method of a MEMS device including laminating a first insulating layer on a main surface of a substrate; laminating a lower-layer wire portion on the first insulating layer so as to be formed; laminating a second insulating layer on the first insulating layer and the lower-layer wire portion; forming a through hole reaching the lower-layer wire portion on the second insulating layer; laminating a sacrificial layer and a MEMS structure on the second insulating layer so as to be formed; forming a sacrificial portion by partitioning the sacrificial layer in a frame shape with a sidewall portion including a wire layer; and etching the sacrificial portion by introducing an etchant, in which, in the forming of the sacrificial portion, the wire layer is laminated and is formed in the through hole so as to form an electrical connection portion which electrically connects the lower-layer wire portion to the MEMS structure.

With this configuration, a wire which is extracted to the outside of the cavity portion from the MEMS structure disposed inside the cavity portion is formed by the lower-layer wire portion provided under the second insulating layer and the electrical connection portion provided in the through hole part formed in the second insulating layer. Therefore, since the wire does not penetrate through the sidewall portion, the wire is not required to be insulated from the sidewall portion. In other words, even in a case where the sidewall portion is conductive (for example, in a case where the sidewall portion is formed by laminating a conductive layer forming a wire of the MEMS device), it is not necessary to provide a coat for insulating the sidewall portion from the electrical connection portion. As a result, an insulating layer such as, for example, a silicon oxide film, with a low etching resistance, which is frequently used in a semiconductor manufacturing process, is not exposed to the cavity portion. For this reason, even if excessive etching is performed, it does not happen that an etchant leaks to outside of the cavity portion due to erosion of the insulating layer with a low etching resistance.

In addition, since the periphery of the sacrificial portion forming the cavity portion is formed only using a material with a high etching resistance such as a metal material, that is, an etching stopper, it is not necessary to strictly manage etching end timing unlike in the related art, and it is possible to take a large management width (margin) of an etching step. As a result, it is possible to perform not insufficient etching but sufficient release-etching without apprehending influence of excessive etching on reliability.

In addition, since an insulating layer such as a silicon oxide film which tends to generate an outgas does not remain in or is not exposed to inside of the cavity portion, the inside of the cavity portion can be maintained in a decompressed state.

As described above, according to the application examples, it is possible to provide a MEMS device having higher reliability through manufacturing steps of which management is further simplified.

### BRIEF DESCRIPTION OF THE DRAWINGS

The invention will be described with reference to the accompanying drawings, wherein like numbers reference like elements.

FIG. 1A is a plan view illustrating a MEMS device according to Embodiment 1, FIG. 1B is a cross-sectional view taken along the line A-A of FIG. 1A, and FIG. 1C is a cross-sectional view illustrating an example of a MEMS structure.

FIG. 2A is a plan view illustrating a configuration example of a MEMS device in the related art, and FIG. 2B is a cross-sectional view of the MEMS device in the related art.

FIGS. 3A to 3G are process diagrams illustrating a manufacturing method of the MEMS device according to Embodiment 1.

FIG. 4A is a perspective view illustrating a configuration of a mobile type personal computer as an example of an electronic apparatus, and FIG. 4B is a perspective view illustrating a configuration of a mobile phone as an example of an electronic apparatus.

FIG. 5 is a perspective view illustrating a configuration of a digital still camera as an example of an electronic apparatus.

FIGS. 6A and 6B are cross-sectional views illustrating variations of a method of connection to a first conductive layer or a second conductive layer at the upper part of the electrical connection portion as modification examples.

### DESCRIPTION OF EXEMPLARY EMBODIMENTS

Hereinafter, embodiments of the invention will be described with reference to the drawings. The following is an embodiment of the invention and is not intended to limit the invention. In addition, in the following respective drawings, for better understanding of description, scales different from actual ones are shown in some cases.

### Embodiment 1

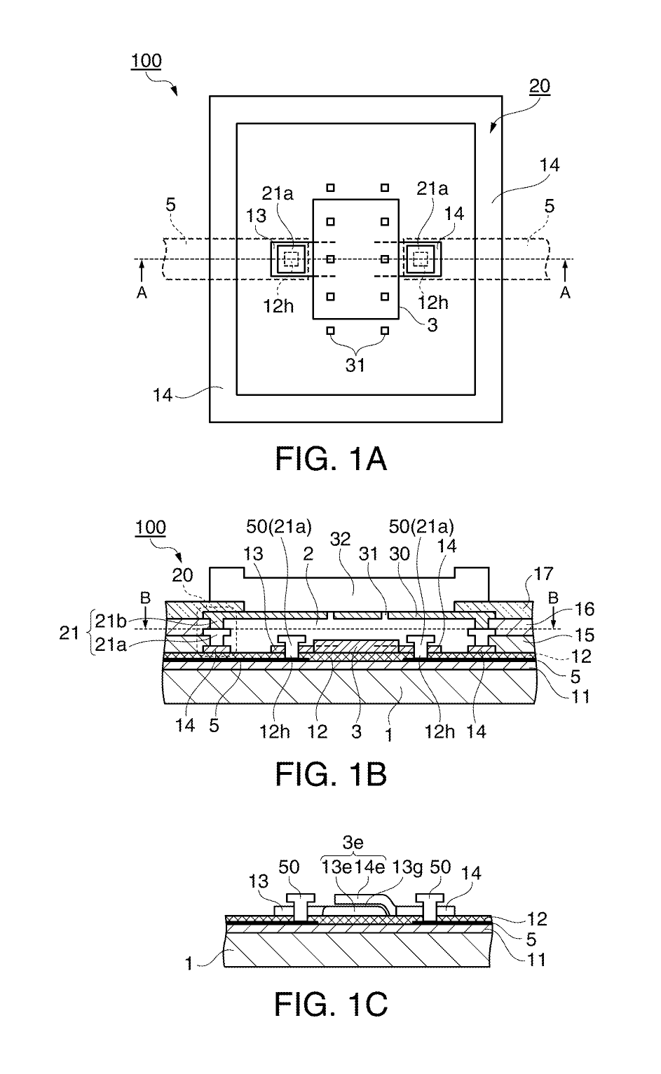

FIG. 1A is a plan view illustrating a MEMS device 100 according to Embodiment 1, FIG. 1B is a cross-sectional view taken along the line A-A of FIG. 1A, and FIG. 1C is a cross-sectional view illustrating an example of a MEMS structure.

FIG. 1A is a plan view taken along the line B-B of FIG. 1B. In addition, in FIG. 1A, openings 31 are also shown for better understanding.

A MEMS device 100 is a MEMS device having a MEMS structure (an electro-mechanical system structure having a mechanically movable structure) disposed in a cavity portion which is formed by etching a sacrificial layer laminated on a main surface of a wafer substrate.

The MEMS device 100 includes a wafer substrate 1, a cavity portion 2, a MEMS structure 3, a lower-layer wire portion 5, a first oxide film 11 which is a first insulating layer, a nitride film 12 which is a second insulating layer, a first conductive layer 13, a second conductive layer 14, a second oxide film 15, a third oxide film 16, a protective film 17, a sidewall portion 20, a wire layer 21, a first coat layer 30, openings 31, a second coat layer 32, an electrical circuit portion (not shown), and the like.

The wafer substrate 1 uses a silicon substrate as a preferred example, and the MEMS structure 3 is formed on the first oxide film 11 and the nitride film 12 laminated on the wafer substrate 1.

In addition, here, the description is made assuming that a direction in which the first oxide film 11 and the nitride film 12 are sequentially laminated on the main surface of the wafer substrate 1 is an upper direction.

The MEMS structure 3 is a structure having a mechanically movable part which is formed by patterning the first conductive layer 13 and the second conductive layer 14 laminated on the nitride film 12 through photolithography, and is disposed in the cavity portion 2 (cavity).

The MEMS structure 3 is a MEMS vibrator 3e as shown in FIG. 1C.

The MEMS vibrator 3e includes a lower electrode 13e and an upper electrode 14e with a movable part. A vacant space 13g forming a movable space of the upper electrode 14e is formed between the lower electrode 13e and the upper electrode 14e. The cavity portion 2 and the vacant space 13g are formed by removing (release-etching) the second oxide film 15 and the third oxide film 16 laminated on the MEMS vibrator 3e, and a fourth oxide film 13f (not shown) formed between the lower electrode 13e and the upper electrode 14e through etching.

The second oxide film 15, the third oxide film 16, and the fourth oxide film 13f are so-called sacrificial layers, and the sacrificial layers are release-etched so as to form a movable electrode structure of a cantilever structure in which the upper electrode 14e is isolated from the lower electrode 13e.

The first conductive layer 13 and the second conductive layer 14 are respectively made of polysilicon as a preferred example, and are not limited thereto. In addition, the MEMS structure 3 is not limited to the MEMS vibrator 3e.

The second oxide film 15 and the third oxide film 16 are oxide films formed through chemical vapor deposition (CVD). FIG. 1B shows that each layer has a single layer structure, but each layer may have a multi-layer structure for planarization.

In release-etching, the sidewall portion 20 is formed as an etching stopper around the sacrificial layers formed by the second oxide film 15 and the third oxide film 16 laminated on the MEMS structure 3, and then release-etching is performed. In other words, the cavity portion 2 formed through the release-etching is partitioned by the sidewall portion 20.

The sidewall portion 20 is formed of the second conductive layer 14, the wire layer 21 (a first wire layer 21a and a second wire layer 21b), and the like, and partitions the cavity portion 2 in a frame shape in plan view of the wafer substrate 1 as shown in FIG. 1A. The second conductive layer 14 is made of conductive polysilicon as a preferred example as described above, and the wire layer 21 is made of aluminum as a preferred example. These layers are resistant to an etchant (for example, buffered hydrofluoric acid), and thus function as an etching stopper. In addition, wire materials are not limited thereto, and may use materials which are used in a semiconductor process.

The second wire layer 21b located at the uppermost part of the sidewall portion 20 is formed so as to cover the cavity portion 2 and constitutes the first coat layer 30. In other words, the first coat layer 30 covers the sidewall portion 20 and the cavity portion 2. The first coat layer 30 (the second wire layer 21b) is provided with a plurality of openings 31 through which an etchant is introduced when the sacrificial layers are release-etched. That is, the openings 31 penetrate to the cavity portion 2. The openings 31 are formed with an interval around the MEMS structure 3 so as to remove the sacrificial layers using an introduced etchant and to thereby reliably form the MEMS structure 3.

The protective film 17 is laminated on the sidewall portion 20. In addition, the second coat layer 32 is laminated on the first coat layer 30 and the protective film 17 after release-etching and cleaning, so as to seal the openings 31.

In addition, a manufacturing method of the MEMS device 100 will be described later.

The first conductive layer 13 and the second conductive layer 14 forming the MEMS structure 3 are electrically connected to the electrical circuit portion disposed outside the cavity portion 2. A wire structure which electrically connects the MEMS structure 3 of the cavity portion 2 to the electrical circuit portion outside the cavity portion 2 is formed by the lower-layer wire portion 5, an electrical connection portion 50, and the like.

The lower-layer wire portion 5 is formed by patterning a conductive layer which is laminated on the first oxide film 11 (the first insulating layer) laminated on the wafer substrate 1, through photolithography. As shown in FIG. 1A, the lower-layer wire portion 5 is patterned so as to extend from the region overlapping the first conductive layer 13 or the second conductive layer 14 to the outside of the sidewall portion 20 formed in a frame shape in plan view of the wafer substrate 1. The conductive layer forming the lower-layer wire portion 5 is formed by sputtering aluminum as a preferred example, but a material of the conductive layer is not limited thereto, and may be gold, copper, or polysilicon. In addition, the material is preferably a conductive material or a wire material forming the electrical circuit portion.

The nitride film 12 (the second insulating layer) is laminated so as to cover the first oxide film 11 and the lower-layer wire portion 5.

In addition, as shown in FIG. 1A, a through hole 12h is formed in a region of the nitride film 12 which overlaps the central part of each region where the first conductive layer 13 or the second conductive layer 14 overlaps the lower-layer wire portion 5 in plan view of the wafer substrate 1. The through hole 12h is a through hole which reaches the surface of the lower-layer wire portion 5 from the surface (upper surface) of the nitride film 12. The electrical connection portion 50 is formed in the through hole 12h so as to block the through hole 12h. A lower part of the electrical connection portion 50 is electrically connected to the lower-layer wire portion 5, and an upper part thereof is exposed so as to be electrically connected to the first conductive layer 13 or the second conductive layer 14 laminated on the nitride film 12.

The electrical connection portion 50 is formed by patterning the first wire layer 21a laminated on the first conductive layer 13 or the second conductive layer 14. In the example shown in FIG. 1B, the electrical connection portions 50 are formed so as to communicate with and block the through holes (through holes connected to the through holes 12h in an overlapping manner) formed in the first conductive layer 13 and the second conductive layer 14, and the side surface of the upper part (a substantially central part in FIG. 1B) of the electrical connection portion 50 is electrically connected to the first conductive layer 13 or the second conductive layer 14.

Further, a method of connection to the first conductive layer 13 or the second conductive layer 14 at the upper part of the electrical connection portion 50 is not limited to this configuration, and may employ, for example, configurations shown in modification examples described later.

In addition, the electrical connection portion 50 is formed using the first wire layer 21a made of aluminum which is a metal material as a preferred example, but is not limited thereto, and may be formed using the second wire layer 21b or a metal wire layer of a further upper layer.

In addition, an external electrical circuit portion may be formed integrally with the MEMS device 100 as a semiconductor circuit. In other words, for example, materials forming the semiconductor circuit can be used in common by using the first oxide film 11 and the nitride film 12 as an element isolation layer of a circuit region forming the electrical circuit portion, using the first conductive layer 13 and the second conductive layer 14 forming the MEMS structure 3 as a gate electrode, using the second oxide film 15, the third oxide film 16, the fourth oxide film 13f, and the protective film 17 as an interlayer insulating layer (insulating film) forming an interlayer insulating portion or a protective film, using the first wire layer 21a and the second wire layer 21b as a circuit wire layer corresponding to an upper-layer wire portion, and the like. In other words, the MEMS device 100 can be formed in manufacturing steps of the semiconductor circuit. Particularly, in a case of a MEMS vibrator having a movable electrode using a semiconductor, the MEMS vibrator can be easily incorporated into a semiconductor process as compared with a vibrator such as a quartz crystal.

A MEMS device in the related art will be described.

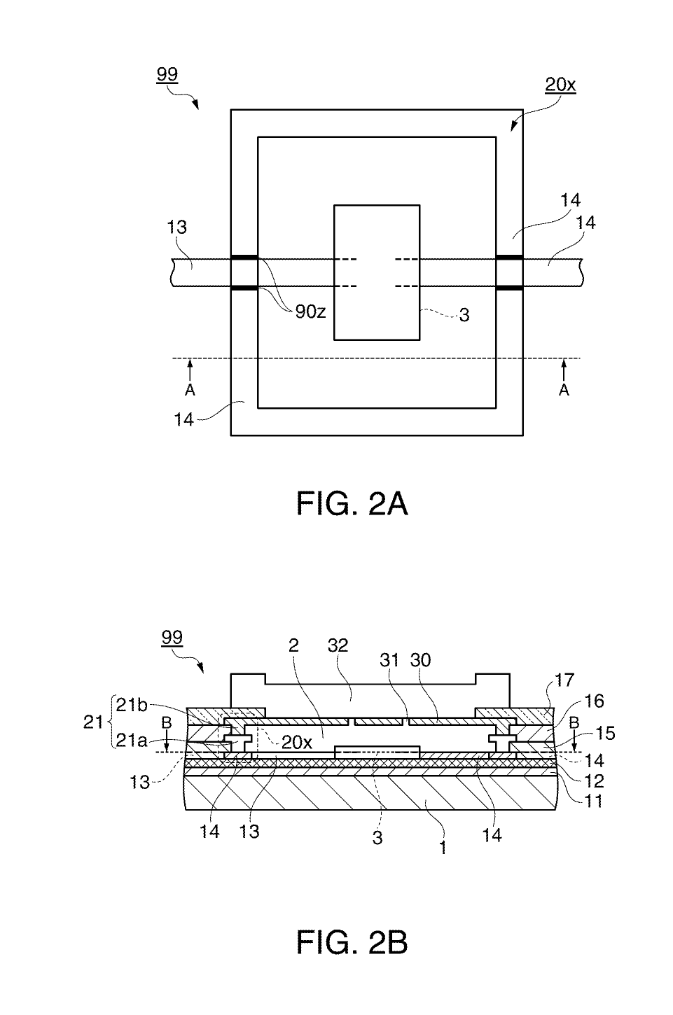

FIGS. 2A and 2B show a configuration example of a MEMS device 99 in the related art. FIG. 2A is a plan view of the MEMS device 99, and FIG. 2B is a cross-sectional view taken along the line A-A of FIG. 2A. In addition, FIG. 2A is a plan view taken along the line B-B of FIG. 2B.

In a case of the MEMS device 99, a wire for electrical connection between the MEMS structure 3 of the cavity portion 2 and an external electrical circuit portion (not shown) of the cavity portion 2 uses a pattern wire formed by the first conductive layer 13 and the second conductive layer 14. As shown in FIG. 2B, the first conductive layer 13 and the second conductive layer 14 are laminated and are formed on the nitride film 12 and are thus required to be insulated from the sidewall portion 20x laminated and formed on the nitride film 12 in the same manner. For this reason, as shown in FIG. 2A, the pattern wire formed by the first conductive layer 13 and the second conductive layer 14 is drawn out through a tunnel structure in which the pattern wire is insulated therefrom by coating a gap with the sidewall portion 20x with an insulating layer 90z.

A silicon oxide film with a low etching resistance is used in the insulating layer 90z so as to have the same configuration as the electrical circuit portion. For this reason, there is a concern that an etchant may permeate into the periphery of the cavity portion 2 via the insulating layer 90z in release-etching for forming the cavity portion 2, and thereby reliability of a peripheral electrical circuit may be reduced.

In manufacturing steps of the MEMS device 99, in order to avoid a reduction in reliability, etching time is managed for preventing excessive etching. On the other hand, if etching is insufficient, there is a case where a sacrificial layer remains, and thus dimension accuracy of the MEMS structure 3 is reduced, or the remaining sacrificial layer generates an outgas inside the cavity. In other words, in a case of the MEMS device 99 in the related art, it is necessary to perform strict management for appropriately setting etching time or etching conditions or suppressing etching disparity.

Next, a manufacturing method of the MEMS device 100 according to Embodiment 1 will be described.

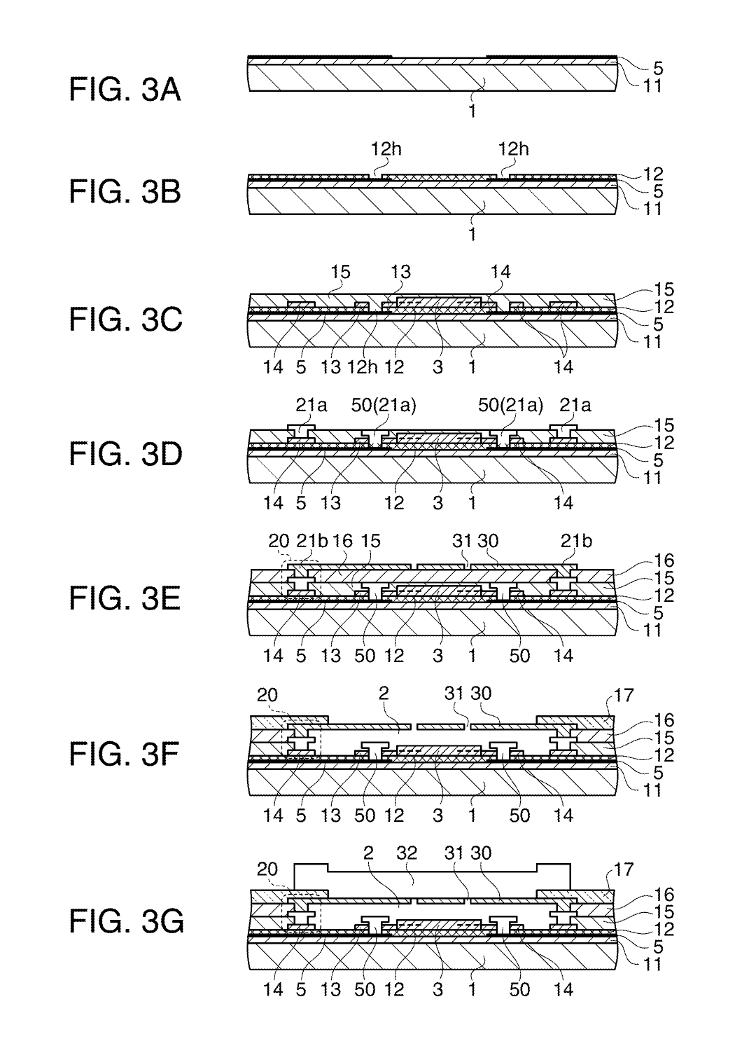

FIGS. 3A to 3G are process diagrams illustrating a manufacturing method of the MEMS device 100 in order.

The manufacturing method of the MEMS device 100 includes a step of laminating the first oxide film 11 which is the first insulating layer on the main surface of the wafer substrate 1; a step of laminating the lower-layer wire portion 5 on the first oxide film 11 so as to be formed; a step of laminating the nitride film 12 which is the second insulating layer so as to cover the first oxide film 11 and the lower-layer wire portion 5; a step of forming the through hole 12h which reaches the lower-layer wire portion 5 in the nitride film 12; a step of laminating the second oxide film 15 and the third oxide film 16 which are sacrificial layers and the MEMS structure 3 on the nitride film 12 so as to be formed; a sacrificial portion forming step of partitioning the second oxide film 15 and the third oxide film 16 in a frame shape by using the sidewall portion 20 including the wire layer 21 so as to form a sacrificial portion; a step of laminating the first coat layer 30 having one or more openings 31 which expose the sacrificial portion so as to cover the sidewall portion 20 and the sacrificial portion; a step of introducing an etchant through the openings 31 so as to etch the sacrificial portion; and a step of laminating the second coat layer 32 on the first coat layer 30 so as to seal the openings 31.

In addition, in the sacrificial portion forming step, the first wire layer 21a is laminated and is formed in the through hole 12h so as to form the electrical connection portion 50 which electrically connects the lower-layer wire portion 5 to the MEMS structure 3.

Hereinafter, a detailed description thereof will be made with reference to FIGS. 3A to 3G.

FIG. 3A: The wafer substrate 1 is prepared, and the first oxide film 11 is laminated on the main surface thereof. The first oxide film 11 is formed of a normal local oxidation of silicon (LOCOS) oxide film which is an element isolation layer in a semiconductor process as a preferred example, but may be an oxide film formed using, for example, a shallow trench isolation (STI) method depending on the generation of the semiconductor process.

Next, the lower-layer wire portion 5 is laminated on the first oxide film 11 so as to be formed. Specifically, the lower-layer wire portion 5 is formed, for example, by sputtering aluminum which is patterned through photolithography. The patterning is performed such that a predetermined arrangement is obtained which extends from a region overlapping the first conductive layer 13 or the second conductive layer 14 formed in the subsequent step to outside of the sidewall portion 20 formed in a frame shape in plan view of the wafer substrate 1.

FIG. 3B: Next, the nitride film 12 is laminated so as to cover the first oxide film 11 and the lower-layer wire portion 5. The nitride film 12 is resistant to a buffered hydrofluoric acid which is an etchant, and thus functions as an etching stopper.

Next, the through hole 12h reaching the lower-layer wire portion 5 is formed in the nitride film 12. A position where the through hole 12h is formed is required to be located in a region where the first conductive layer 13 or the second conductive layer 14 which is formed in the subsequent step and is to be connected overlaps the lower-layer wire portion 5 and where the first oxide film 11 is not exposed, in plan view of the wafer substrate 1. The reason why the first oxide film 11 is not made to be exposed is that a hole is formed in the nitride film 12 which functions as an etching stopper due to the through hole 12h and thereby the first oxide film 11 is etched when the first oxide film 11 is exposed. A part of the lower-layer wire portion 5 exposed by the through hole 12h functions as an etching stopper, and thus the underlying first oxide film 11 is not etched.

FIG. 3C: Next, the second oxide film 15 forming the MEMS structure 3 and some sacrificial layers is laminated on the nitride film 12 so as to be formed.

Specifically, first, the first conductive layer 13 is laminated on the nitride film 12 and is patterned through photolithography. The first conductive layer 13 is a polysilicon layer forming a part of the MEMS structure 3, and is made to have a predetermined conductivity by implanting ions thereinto after being laminated. Next, a necessary sacrificial layer is formed between the first conductive layer 13 and the second conductive layer 14. For example, in a case of the MEMS vibrator 3e (FIG. 1C), the fourth oxide film 13f is formed on the surface of the lower electrode 13e through thermal oxidization.

Next, the second conductive layer 14 is laminated and is patterned through photolithography. The second conductive layer 14 is a polysilicon layer forming a part of the MEMS structure 3 and the lowermost layer of the sidewall portion 20, and is made to have a predetermined conductivity by implanting ions thereinto after being laminated.

The patterning of the first conductive layer 13 and the second conductive layer 14 is performed such that a predetermined MEMS structure 3 is formed, and the through hole 12h is formed in a region of the nitride film 12 which overlaps the central part of each region where the first conductive layer 13 or the second conductive layer 14 overlaps the lower-layer wire portion 5 in plan view of the wafer substrate 1. In addition, in a case where the electrical connection portion 50 is formed so as to penetrate through the first conductive layer 13 or the second conductive layer 14, a through hole is formed at the position overlapping the through hole 12h, as shown in FIG. 3C.

Next, the second oxide film 15 forming some sacrificial layers is laminated. The second oxide film 15 is formed as an interlayer film (inter-metal dielectric (IMD)) in a semiconductor process, and is planarized using tetraethoxysilane (TEO) as a preferred example. The planarization may be performed using chemical mechanical polishing (CMP) depending on the generation of a semiconductor process.

FIG. 3D: Next, the second oxide film 15 is patterned through photolithography before the first wire layer 21a is laminated. Specifically, holes (exposing portion), which expose corresponding regions (connection portion) of the first conductive layer 13, the second conductive layer 14, the lower-layer wire portion 5, and the like electrically connected to the first wire layer 21a, are formed in the second oxide film 15, including a region forming a part of the sidewall portion 20 using the first wire layer 21a and the through hole 12h.

Next, the first wire layer 21a is laminated and is patterned through photolithography. The first wire layer 21a laminated on the through hole 12h forms the electrical connection portion 50, and is electrically connected to a part which comes into contact with the electrical connection portion 50.

Aluminum is laminated in the first wire layer 21a through sputtering as a preferred example.

In addition, since the electrical circuit portion is not shown in FIG. 3D, the first wire layer 21a is shown only in the second layer part forming the sidewall portion 20, and the through hole 12h part.

FIG. 3E: Next, the third oxide film 16 is laminated as a layer forming some sacrificial layers. The third oxide film 16 may have, for example, a three-layer structure for planarization. In this case, first, a CVD oxide film is laminated in the first layer of the three layers, and, further, an SOG film is formed in the second layer and undergoes a planarization process. A CVD oxide film is laminated in the third layer again. The third oxide film 16 is formed as an interlayer film (inter layer dielectric (IMD)) in a semiconductor process, and may be planarized using CMP or the like depending on the generation of a semiconductor process.

Next, before the second wire layer 21b is laminated, a hole (exposing portion) for electrical connection between the first wire layer 21a and the second wire layer 21b is formed in the third oxide film 16 through photolithography. Next, the second wire layer 21b is laminated and is patterned through photolithography. The second wire layer 21b forms the uppermost layer of the sidewall portion 20, is provided with the openings 31 for release-etching the sacrificial layer of the MEMS device 100, and covers the sacrificial layer (the third oxide film 16). The second wire layer 21b forms the first coat layer 30.

In addition, aluminum is laminated in the second wire layer 21b through sputtering as a preferred example.

The step described in FIGS. 3D and 3E is a sacrificial portion forming step in which the second oxide film 15 and the third oxide film 16 are partitioned in a frame shape by the sidewall portion 20 including the wire layer 21, so as to form a sacrificial portion. In this sacrificial portion forming step, the first wire layer 21a is laminated and is formed on the through hole 12h so as to form the electrical connection portion 50 for electrical connection between the lower-layer wire portion 5 and the MEMS structure 3.

FIG. 3F: The protective film 17 is laminated, is provided with an opening portion so as to expose the openings 31, and is patterned through photolithography. The protective film 17 may be a normal protective film (for example, a SiO₂ film or a two-layer film of SiN) in a semiconductor process, a polyimide film, or the like.

Next, the wafer substrate 1 is exposed to an etchant so as to release-etch the second oxide film 15, the third oxide film 16, and the fourth oxide film 13f (in a case where the MEMS structure 3 is the MEMS vibrator 3e as shown in FIG. 1C) which are sacrificial layers, thereby forming the MEMS structure 3.

FIG. 3G: After the release-etching finishes and cleaning is performed, the second coat layer 32 is laminated, and is patterned through photolithography such that a part which is not covered by the protective film 17 is sealed. The openings 31 are sealed by the second coat layer 32, and the space from which the sacrificial layers are removed through the release-etching is maintained in an airtight state. The second coat layer 32 uses aluminum as a preferred example, but is not limited thereto and may use other metals layers.

As described above, the following effects can be achieved according to the MEMS device and the manufacturing method of the MEMS device of the present embodiment.

According to the application example, the MEMS device 100 includes the first oxide film 11 which is the first insulating layer laminated on the main surface of the wafer substrate 1; the lower-layer wire portion 5 which is laminated on the first oxide film 11 so as to be formed; the nitride film 12 which is the second insulating layer so as to cover the first oxide film 11 and the lower-layer wire portion 5; the sidewall portion 20 which is laminated on the nitride film 12 so as to be formed in a frame shape; the cavity portion 2 which is formed by etching the sacrificial portion which is partitioned planarly by the sidewall portion 20; the MEMS structure 3 which is disposed in the cavity portion 2; the first coat layer 30 which is laminated so as to cover the sidewall portion 20 and the cavity portion 2 and has one or more openings 31 which penetrate to the cavity portion 2; and the second coat layer 32 which is laminated on the first coat layer and seals the openings 31. In addition, the nitride film 12 has the through hole 12h which reaches the lower-layer wire portion 5, and the MEMS structure 3 and the lower-layer wire portion 5 are electrically connected to each other by the electrical connection portion 50 which is laminated and is formed so as to block the through hole 12h.

According to this structure, a wire which is extracted to the outside of the cavity portion 2 from the MEMS structure 3 disposed inside the cavity portion 2 is formed by the lower-layer wire portion 5 provided under the nitride film 12 and the electrical connection portion 50 provided in the through hole 12h part formed in the nitride film 12. Therefore, since the wire does not penetrate through the sidewall portion 20, the wire is not required to be insulated from the sidewall portion 20. In other words, even in a case where the sidewall portion 20 is conductive (for example, in a case where the sidewall portion 20 is formed by laminating a conductive layer forming a wire of the MEMS device 100), it is not necessary to provide a coat for insulating the sidewall portion 20 from the electrical connection portion 50. As a result, an insulating layer such as, for example, a silicon oxide film, with a low etching resistance, which is frequently used in a semiconductor manufacturing process, is not exposed to the cavity portion 2. For this reason, even if excessive etching is performed, it does not happen that an etchant leaks to outside of the cavity portion 2 due to erosion of the insulating layer with a low etching resistance.

In addition, since the periphery of the sacrificial portion forming the cavity portion 2 is formed only using a material with a high etching resistance such as a metal material, that is, an etching stopper, it is not necessary to strictly manage etching end timing, and it is possible to take a large management width (margin) of an etching step. As a result, it is possible to perform not insufficient etching but sufficient release-etching without apprehending influence of excessive etching on reliability.

In addition, since an insulating layer such as a silicon oxide film which tends to generate an outgas does not remain in or is not exposed to inside of the cavity portion 2, the inside of the cavity portion 2 can be maintained in a decompressed state.

As above, according to the present embodiment, it is possible to provide a MEMS device having higher reliability through manufacturing steps of which management is further simplified.

### Electronic Apparatus

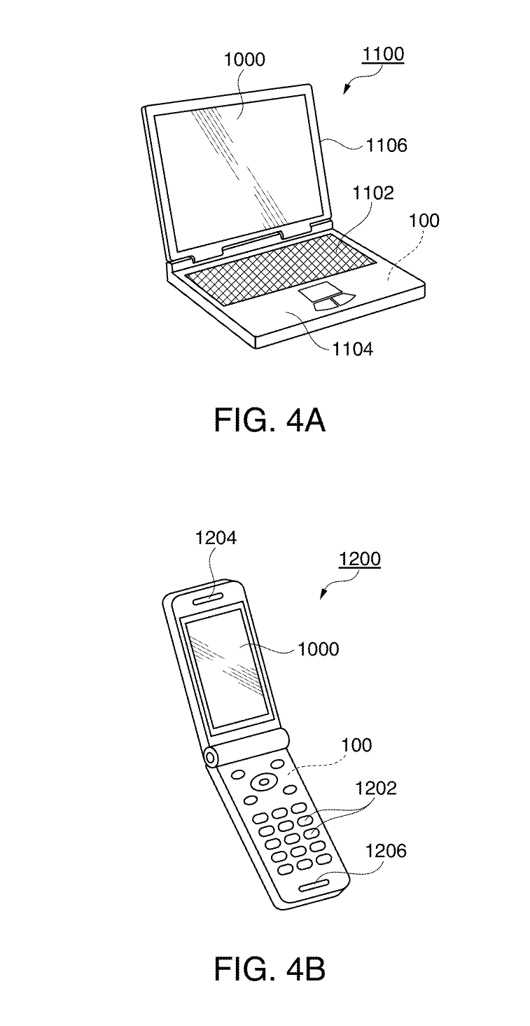

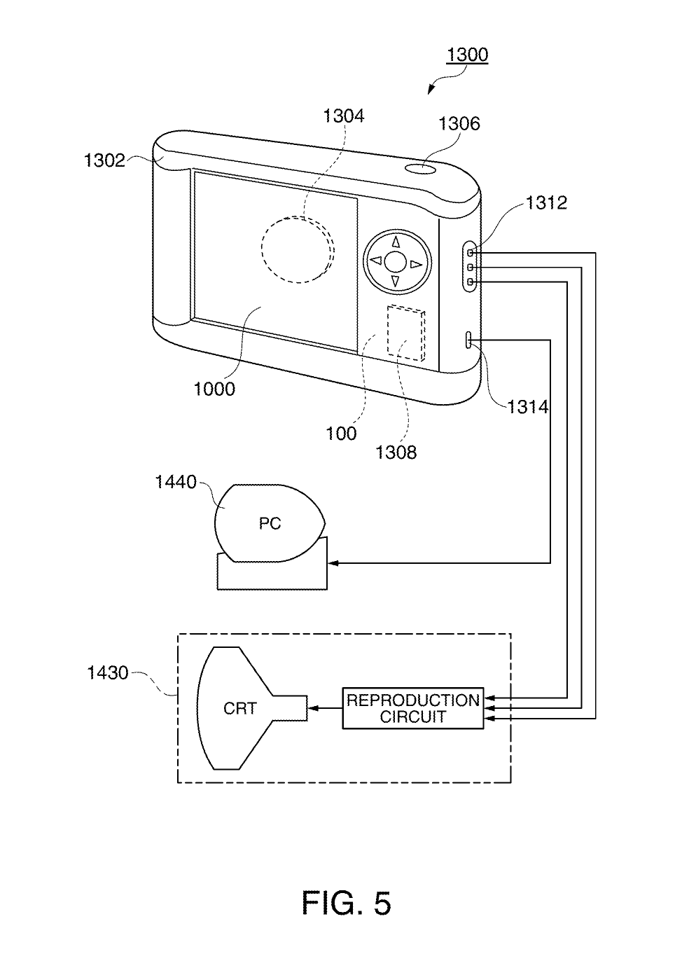

Next, a description will be made of electronic apparatuses which employ the MEMS device 100 as an electronic component according to an embodiment of the invention with reference to FIGS. 4A, 4B and 5.

FIG. 4A is a perspective view illustrating a schematic configuration of a mobile type (or a notebook type) personal computer which is an electronic apparatus including the electronic component according to the embodiment of the invention. In FIG. 4A, a personal computer 1100 includes a main body unit 1104 provided with a keyboard 1102 and a display unit 1106 provided with a display portion 1000, and the display unit 1106 is supported by the main body unit 1104 via a hinge structure portion so as to be rotatably moved. The MEMS device 100, which is an electronic component functioning as a filter, a resonator, a reference clock, and the like, is embedded in the personal computer 1100.

FIG. 4B is a perspective view illustrating a schematic configuration of a mobile phone (also including PHS) which is an electronic apparatus including the electronic component according to the embodiment of the invention. In FIG. 4B, a mobile phone 1200 includes a plurality of operation buttons 1202, an ear piece 1204, and a mouth piece 1206, and a display portion 1000 is disposed between the operation buttons 1202 and the ear piece 1204. The MEMS device 100, which is an electronic component (a timing device) functioning as a filter, a resonator, an angular velocity sensor, and the like, is embedded in the mobile phone 1200.

FIG. 5 is a perspective view illustrating a schematic configuration of a digital still camera which is an electronic apparatus including the electronic component according to the embodiment of the invention. In addition, in FIG. 5, connections to an external apparatus are simply shown. The digital still camera 1300 performs photoelectric conversion on a light image of a subject by using an imaging device such as a charge coupled device (CCD) so as to generate an imaging signal (an image signal).

A display portion 1000 is provided on a rear surface of a case (body) 1302 of the digital still camera 1300, and performs display based on an imaging signal generated by a CCD, and the display portion 1000 functions as a finder which displays a subject as an electronic image. In addition, alight sensing unit 1304 which includes an optical lens (imaging optical system), a CCD, and the like is provided on a front surface side (the other side of FIG. 7) of the case 1302.

When a photographer checks a subject image displayed on the display portion 1000 and pushes a shutter button 1306, an imaging signal of the CCD at that point is transferred to and is stored in a memory 1308. In addition, video signal output terminals 1312 and an input and output terminal 1314 for data communication are provided on the side surface of the case 1302 in the digital still camera 1300. In addition, as shown in FIG. 5, a television monitor 1430 is connected to the video signal output terminals 1312, and a personal computer 1440 is connected to the input and output terminal 1314 for data communication, as necessary. Further, the imaging signal stored in the memory 1308 is output to the television monitor 1430 or the personal computer 1440 through a predetermined operation. The MEMS device 100, which is an electronic component functioning as a filter, a resonator, an angular velocity sensor, and the like, is embedded in the digital still camera 1300.

Further, in addition to the personal computer (a mobile type personal computer) of FIG. 4A, the mobile phone of FIG. 4B, and the digital still camera of FIG. 5, the MEMS device 100 which is an electronic component according to an embodiment of the invention is applicable to, for example, an ink jet type ejection apparatus (for example, an ink jet printer), a laptop type personal computer, a television, a video camera, a car navigation apparatus, a pager, an electronic organizer (including a communication function portion), an electronic dictionary, an electronic calculator, an electronic gaming machine, a workstation, a videophone, a security television monitor, an electronic binocular, a POS terminal, a medical apparatus (for example, an electronic thermometer, a sphygmomanometer, a blood glucose monitoring system, an electrocardiographic apparatus, an ultrasonic diagnostic apparatus, or an electronic endoscope), a fish-finder, various measurement apparatuses, meters and gauges (for example, meters and gauges of vehicles, aircrafts, and ships), a flight simulator, and the like.

In addition, the invention is not limited to the above-described embodiments, and may add various modifications or alterations to the above-described embodiments. Modification examples will be described below. Here, the same constituent element as in the above-described embodiments is given the same reference numeral, and repeated description will be omitted.

### Modification Examples

A method of connection to the first conductive layer 13 or the second conductive layer 14 at the upper part of the electrical connection portion 50 is not limited to the configuration of Embodiment 1, and may have the following configurations.

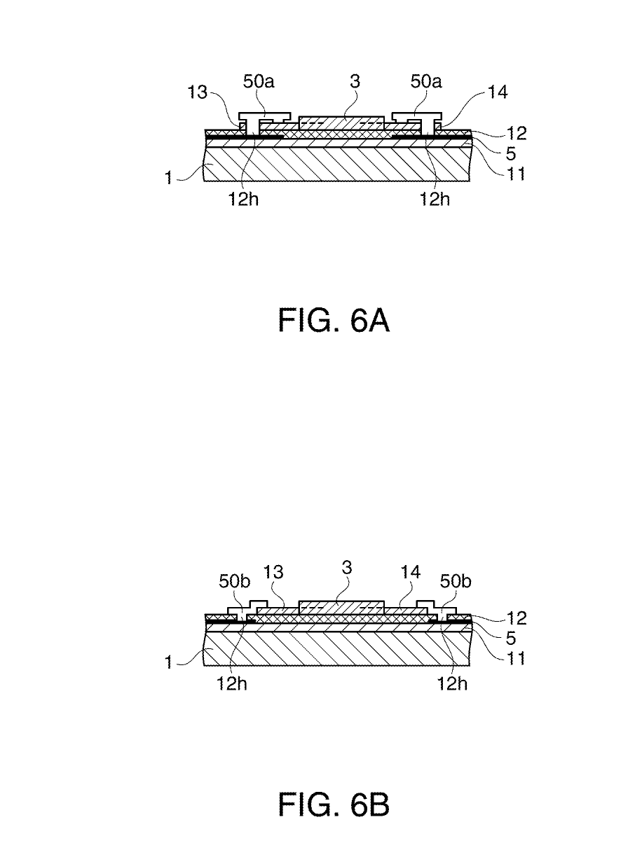

FIGS. 6A and 6B are cross-sectional views illustrating variations of a method of connection of the electrical connection portion 50 to a first conductive layer 13 or a second conductive layer 14 at the upper part of the electrical connection portion 50 as modification examples. In either case, there is a feature in which the area of the electrical connection portion 50 is larger than the area of the through hole 12h in plan view of the wafer substrate 1.

In the example shown in FIG. 6A, an upper part of an electrical connection portion 50a is formed so as to expand on the first conductive layer 13 or the second conductive layer through patterning using photolithography, thereby increasing the number of contact parts or the contact area between the electrical connection portion 50a and the first conductive layer 13 or the second conductive layer 14. With the above-described configuration, it is possible to further reduce electrical resistance at the connection portion.

In addition, although, in Embodiment 1, a case has been described in which the lower-layer wire portion 5 is patterned from the region overlapping the first conductive layer 13 or the second conductive layer 14 to the outside of the sidewall portion 20 formed in a frame shape in plan view of the wafer substrate 1 as shown in FIG. 1A, the lower-layer wire portion 5 is not necessarily required to be formed at a position overlapping the first conductive layer 13 or the second conductive layer 14.

As in an electrical connection portion 50b shown in FIG. 6B, an upper part thereof is formed and is disposed as a wire pattern on an upper part of the nitride film 12, the first conductive layer 13 or a second conductive layer 14, and thereby the lower-layer wire portion 5 can be electrically connected to the first conductive layer 13 or the second conductive layer 14 without overlapping each other (in plan view of the wafer substrate 1). The area of the upper part of the electrical connection portion 50b is increased through patterning using photolithography so as to increase the area in which the upper part is laminated on the first conductive layer 13 or the second conductive layer 14, and thereby it is possible to further reduce electrical resistance at the connection portion.

Further, since the electrical connection portion 50b can cover the lower-layer wire portion 5 which is exposed by the through hole 12h, it does not happen that an etchant for etching a sacrificial layer enters the through hole 12h and remains therein or leaks to apart such as the insulating layer for insulating the lower-layer wire portion 5 and causes erosion. As a result, it is possible to provide a MEMS device with higher reliability.

The entire disclosure of Japanese Patent Application No. 2012-186181, filed Aug. 27, 2012 is expressly incorporated by reference herein.

What is claimed is:

1. A MEMS device comprising:
a first insulating layer that is laminated above a main surface of a substrate;
a lower-layer wire portion that is disposed above the first insulating layer;
a second insulating layer that is laminated above the first insulating layer and the lower-layer wire portion;
a sidewall portion that is laminated above the second insulating layer and is formed in a frame shape;
a cavity portion that is partitioned by the sidewall portion; and
a MEMS structure that is disposed in the cavity portion,
wherein the second insulating layer includes a through hole reaching the lower-layer wire portion, and
wherein the MEMS structure is electrically connected to the lower-layer wire portion by an electrical connection portion provided in the through hole.

2. The MEMS device according to claim 1, further comprising:
an electrical circuit portion including the first insulating layer, the second insulating layer, a conductive layer forming the MEMS structure, and an upper-layer wire portion and an interlayer insulating portion laminated and formed above the second insulating layer,
wherein the electrical connection portion is formed of an upper-layer wire layer which forms the upper-layer wire portion, and
the cavity portion is formed by etching a sacrificial portion which is formed of an interlayer insulating layer forming the interlayer insulating portion.

3. The MEMS device according to claim 1, wherein the electrical connection portion is made of a metal material.

4. The MEMS device according to claim 1, wherein the area of the electrical connection portion is larger than the area of the through hole in plan view of the substrate.

5. An electronic apparatus comprising the MEMS device according to claim 1.

6. A manufacturing method of a MEMS device comprising:
laminating a first insulating layer above a main surface of a substrate;
laminating a lower-layer wire portion above the first insulating layer so as to be formed;
laminating a second insulating layer above the first insulating layer and the lower-layer wire portion;
forming a through hole reaching the lower-layer wire portion above the second insulating layer;
laminating a sacrificial layer and a MEMS structure above the second insulating layer so as to be formed;
forming a sacrificial portion by partitioning the sacrificial layer in a frame shape with a sidewall portion including a wire layer; and
etching the sacrificial portion,
wherein, in the forming of the sacrificial portion, the wire layer is laminated and is formed in the through hole so as to form an electrical connection portion which electrically connects the lower-layer wire portion to the MEMS structure.
